(19) United States
(12) Patent Application Publication
(10) Pub. No.: US 2010/0059084 A1
(43) Pub. Date: Mar. 11, 2010

(54) CLEANING AND TESTING IONIC CLEANLINESS OF ELECTRONIC ASSEMBLIES

(75) Inventor: Steve Stach, Leander, TX (US)

Correspondence Address: PATTON BOGGS LLP, 8484 WESTPARK DRIVE, SUITE 900, MCLEAN, VA, 22102, US

(73) Assignee: Austin American Technology Corporation, Burnet, TX (US)

(21) Appl. No.: 12/547,997

(22) Filed: Aug. 26, 2009

Related U.S. Application Data
(60) Provisional application No. 61/095,906, filed on Sep. 10, 2008.

(51) Int. Cl. B08B 3/12; G01R 27/08

(52) U.S. Cl. 134/1; 134/184; 324/691

(57) ABSTRACT

Systems, methods and processes for cleaning and testing electronic assemblies are described. A cleaning and testing apparatus may include a cleaning chamber, a solvent input into the cleaning chamber, a resistivity sensor within the cleaning chamber for sensing resistivity of the solvent; and a solvent output for removing the solvent from the cleaning chamber. The cleaning chamber may receive one or more electronic assemblies. A user may initiate a cleaning cycle, a testing cycle or a cleaning cycle followed by a testing cycle. The one or more electronic assemblies may be contacted with a solvent. Resistivity of the solvent after contact with the electronic assemblies may be measured and compared with an original resistivity of the solvent before contact with the electronic assemblies. The amount of ionic residues on the electronic assemblies may be determined based upon the comparing step.

### CROSS REFERENCE TO RELATED APPLICATION

This application claims priority to U.S. Provisional Patent Application No. 61/095,906, filed Sep. 10, 2008; the content of which is incorporated by reference herein in its entirety.

### FIELD OF THE INVENTION

The present invention relates to electronic assemblies and, more specifically, to systems, methods and processes for cleaning electronic assemblies and/or testing ionic residues on electronic assemblies.

### BACKGROUND OF THE INVENTION

Product reliability may be directly related to ionic cleanliness of electronic assemblies. Ionic residues must be removed from electronic assemblies during a cleaning process to ensure reliable performance of those electronic assemblies. Ionic residues may arise from sources including fluxes. A flux is a chemical cleaning agent that facilitates soldering, brazing, and welding by removing oxidation from metals to be joined. A primary purpose of flux is to prevent oxidation of the base and filler materials and is important in the creation of electronic assemblies. Use of flux during creation of electronic assemblies, however, may leave unwanted ionic residues on the electronic assemblies. Therefore, much time and capital is spent on assembly lines worldwide to control ionic residues.

The Resistivity of Solvent Extract (“ROSE”) test has been the industry standard production line test for measuring the cleanliness of electronic assemblies for approximately forty years. Originally established as a test for military electronic hardware soldered with Rosin Mildly Activated (“RMA”) fluxes, the test is performed by flowing a 75%/25% mixture of isopropyl alcohol (“IPA”) and de-ionized water across the surface of a previously cleaned electronic assembly and measuring the drop in resistivity of the IPA/water mixture. The ROSE test was incorporated into military specifications (Mil-P-22809) in the 1970's as a final cleanliness requirement for building circuit assemblies for military hardware.

Practicality demanded an automated method of running the ROSE test. Various suppliers responded quickly and developed automated testers where the IPA/water mixture was reused by incorporating a de-ionizing mixed bed filter. The automated ROSE test remains the current standard for conducting daily production tests for electronic assemblies.

In the late 1980's the military adopted industry standards developed jointly through the IPC. The industry standards developed jointly through the IPC kept the ROSE test as the daily standard for class 3 (high reliability electronics) products, but allowed the use of many new types of fluxes for other classes of products. Flux chemistry determines what solvent is suitable for removing a particular flux. The newly approved types of fluxes contained many new resins that were not necessarily soluble in the standard 75%/25% IPA/water mixture. As a result of the use of the new types of fluxes, new systems attempted to use differing ratios of IPA mixed with water in combination with heating of the mixture to improve solubility. The more recent IPC TM-650 standards suggest n-propanol or other alcohols, with water, have been substituted for IPA/water mixture. These attempts met with limited success. Acerbating the problem, the continual miniaturization of electronic assemblies created further problems dissolving ionic residues in hidden smaller spaces.

Measurement using the ROSE test relies on dissolving the ionic residues that are bound in an organic flux matrix, to measure the effect on resistivity. Thus, if the ionic residues are not dissolved in the IPA/water mixture, then any undissolved ionic residues are not detected by the ROSE test, which results in an inaccurate determination of the cleanliness of the electronic assemblies. The limitations of current methods, including tighter geometries for electronic assemblies and new soldering materials/methods, leave companies producing high reliability military and medical hardware with significant exposure due to the lack of acceptable cleaning and testing systems.

One approach to overcome these problems is to use other solvents or solvent blends that have improved solubility when extracting particular ionic residues. Current testers are limited on the range of useful solvent blends due to compatibility problems with ion exchange resins and the materials of construction currently used in commercially available “ROSE” cleanliness testers. The current ion exchange resins are designed for use with water and are compatible with very few organic solvents. Additionally, the both the tanks and the ion exchange resins are usually constructed on a base of plastics like acrylics and polyvinylchloride (“PVC”), which are not generally compatible with organic solvents.

Needs exist for improved systems, methods and processes for cleaning and testing electronic assemblies.

### SUMMARY OF THE INVENTION

Embodiments of the present invention solve many of the problems and/or overcome many of the drawbacks and disadvantages of the prior art by providing systems, methods and processes for cleaning and testing electronic assemblies.

Embodiments of the present invention may include systems, methods and processes for cleaning and testing electronic assemblies. A testing apparatus may include a cleaning/testing area, a solvent input into the cleaning/testing area, a resistivity sensor positioned for sensing resistivity of the solvent within the cleaning chamber; and a solvent output for removing the solvent from the cleaning/testing. It also may include a means physically agitating and/or heating the solvent to improve the dissolution rate and an ion exchange resin to purify the test solvent. The cleaning chamber may receive one or more electronic assemblies. A user may initiate a testing cycle. The one or more electronic assemblies may be contacted with a solvent. Resistivity of the solvent after contact with the electronic assemblies may be measured and compared with an original resistivity of the solvent before contact with the electronic assemblies. The amount of ionic residues on the electronic assemblies may be determined based upon the comparing step.

Additional features, advantages, and embodiments of the invention are set forth or apparent from consideration of the following detailed description, drawings and claims. Moreover, it is to be understood that both the foregoing summary of the invention and the following detailed description are exemplary and intended to provide further explanation without limiting the scope of the invention as claimed.

### BRIEF DESCRIPTION OF THE DRAWINGS

The accompanying drawings, which are included to provide a further understanding of the invention and are incorporated in and constitute a part of this specification, illustrate preferred embodiments of the invention and together with the detailed description serve to explain the principles of the invention. In the drawings:

FIG. 1 is a front view of a cleaning apparatus according to one embodiment.

FIG. 2 is a side view of a cleaning apparatus according to one embodiment.

FIG. 3 is a schematic of a cleaning apparatus according to one embodiment.

### DETAILED DESCRIPTION OF THE PREFERRED EMBODIMENTS

Embodiments of the present invention may provide cleaning and testing apparatus and processes for determining an amount of ionic residue on electronic assemblies.

In certain embodiments, a cleaning apparatus may operate as a testing apparatus or as a multifunction apparatus. The apparatus may be constructed of stainless steel or other materials that are compatible with a variety of organic solvents or blends of solvents. In certain embodiments, glass and/or solvent resistant plastics, such as, for example, polypropylene, polyethylene, Teflon and glass filled nylon66, can be used depending on temperature and the solvent system. In existing systems, materials of construction for tanks in most ionic cleanliness testers are PVC or CPVC. PVC and CPVC, however, are generally not resistant to a wide range of solvents such as those that may be used to formulate better solvent blends. In embodiments of the present invention, ion exchange resins may be used to cleanse the solvent of ions dissolved in the cleaning or testing process. Ion exchange resins may be traditional resins or may be special resins selected for organic solvent compatibility. Ionic resins used may include, for example, a stoichiometric mixture of ROHM HAAS AMBERLYST 15 WET and AMBERLYST A26 OH resins. Special solvents for removing resins may be described in U.S. Pat. No. 5,733,378. U.S. Pat. No. 5,733,378 is incorporated by reference herein in its entirety. Special solvents may include, but are not limited to, solvent blends with the following characteristics:

a. Effective in removing (dissolving) rosin fluxes without traces of “white residue”.

b. Compatible with hardware equipment and components (specifically resin cartridges).

c. Conductive with a measurable specific resistivity in its pure state and able to produce solvent-ion and ion-ion interactions that do not compromise resistivity measurements as a function of the ionic concentration.

d. Low boiling point (this is essential for fast air drying).

e. Non-flammable (combustible is acceptable, with a F.P.>107° F.).

f. Chemically compatible with printed circuit board (“PCB”) components.

g. Non-toxic (preferably with a health hazard rating of 1 or 0).

A homogenous, thermodynamically stable blend of Propylene Glycol Methyl Ether Acetate (“PMA”) and Propylene Glycol Propyl Ether (“PNP”) may be used in embodiments of the apparatus, methods and processes described herein. This blend can be modified to vary specific resistivity by the addition of smaller highly polar compounds in small concentrations up to approximately 5% (i.e., water, alcohols). In addition, small amounts of surfactants may be added to lower the surface tension even further (in most cases, this is not necessary). This blend may effectively dissolve most organic flux residues as well as inorganic contaminants due to a dual organic/aqueous continuous phase.

Solvents designed for use with embodiments of the present invention may be specially formulated for dissolving specific ionic residues. Solvents may include non-alcohol, oxygenated hydrocarbons such as glycols, glycol ethers, glycol esters, esters, and ketones. Blends of these with traditional alcohols may be useful. For flux residues requiring a high dispersion solubility parameter, an aliphatic or aromatic hydrocarbon may be blended with an oxygenated hydrocarbon to achieve a higher dispersion parameter. Chlorinated solvents such as methylene chloride or n-propyl bromide can be used to increase the dispersion parameter and decrease the flash point of the mixture, making it safer to use and transport. Solvents may be chosen based upon a particular circumstance, the resin used, the temperature used, etc.

There are four methods currently approved by the industrial standards committees of IPC for measuring ionic residue levels on circuit assemblies. These methods are specified in industry standard IPC-TM-650 methods, 2.3.25, 2.3.26a, 2.3.26-1 and 2.3.28. The methods either specify or allow for a mixture of isopropyl alcohol and water as the extraction solvent. Method 2.3.26a allows the use of pure water or water/alcohol mixtures. Method 2.3.26a goes on to say “Various alcohols have been used successfully. The preferred systems use either N-propanol or isopropanol.” Flux residues have very different solubility parameters depending on type, manufacture, the thermal profile in the soldering process. Therefore, new solvent blends may be required for new flux types.

Furthermore, new solvents blends may be developed for each flux type or electronic assembly geometric spacing requirements. The primary de-fluxing operation is best accomplished today with combination of aggressive chemicals and physical energy. For water based systems, a combination of water soluble solvents and amines, such as monoethanol amine, are sprayed with high impingement energy at temperatures from 120 to 150° F. Solvent based cleaning systems utilize hydrocarbons such as terpenes. Both usually require a water rinse and heated dry. The exception is vapor degreasing, which does not require a water rinse. Vapor degreasing solvents are usually azeotropic blends of a halogenated solvent (n-propyl bromide) and an alcohol.

Embodiments of the present invention may incorporate a closed tank process that meets new volatile organic compound (“VOC”) requirements. Embodiments of the present invention may be explosion resistant. Additionally, embodiments of the present invention may dry the electronic assemblies at the end of a testing cycle. When combined with a closed tank process, the drying process may eliminate operator exposure to testing solvents that are flammable, such as IPA, or combustible.

Systems, methods and processes may provide local, verifiable cleaning support to manufacturing operations such as touch-up, add-ons, engineering change orders (“ECOs”), product development, and pre-conformal coating cleaning.

Embodiments of the present invention may clean flux residues with a single-solvent, spray under immersion cleaning process. The spray under immersion process is much like a Jacuzzi bath where the nozzles spray under the liquid. There are two reasons this has become the standard for ionic cleanliness testers: (1) Minimization of carbon dioxide interference. Carbon dioxide is absorbed by the water, thus creating carbonic acid, an ionic species. This may cause the base line to drift in proportion to the amount absorbed; (2) Spraying a flammable or combustible fluid in air is inherently unsafe. Alternatively to a single solvent, multiple solvents may be mixed in particular situations. The cleaning process may be followed with an automatic measurement of the ionic cleanliness of an electronic assembly. A built in dryer may complete the cleaning/testing cycle.

In certain embodiments, the cleaning system may be sealed. Sealing the cleaning system may minimize solvent use and limits user exposure. In certain exemplary embodiments, less than 100 gallons per year of solvent may be used. Other amounts of solvents may be used depending on system requirements. The solvents may be used and stored in closed stainless steel tanks. The solvents may be automatically renewed using an ion exchange resin tank, preferably a mixed-bed resin. The mixed bed ion exchange resin tank may remove anionic and cationic soils from the cleaning solvent.

An exemplary method used to assess cleanliness is based upon the ROSE test. As discussed above, the ROSE test relies on dissolving ionic residues in a 75%/25% mixture of IPA and water. Many fluxes are only marginally soluble in this cleaning fluid. If the ionic residues are not dissolved during the ROSE test, then the remaining ionic residues are not detected by the ROSE test. It is well-know that even RMA fluxes can leave white residue when cleaned in IPA/water solutions.

Exemplary embodiments of the present invention may use solvent blends other than 75%/25% IPA/water. The other solvent blends may have improved solubility to extract the ionic residues. Current testers, however, are limited due to compatibility problems with older style ion exchange resins. The older style ion exchange resins are designed for use with water and are compatible with very few organic solvents.

Generally, the resistivity and ionic level of any cleaning solution can be mathematically calculated for any cleaning solvent by the following equation:

1/R=A+(B×√ C)

The constants A and B are determined empirically for each solvent/blend by plotting 1/R versus ionic concentration. A is the Y axis intercept and B is the slope of the line generated. Once these constants are known for a cleaning solution, the ionic levels can be measured via solution resistance.

Embodiments of the present invention may use the above correlation in combination with specific solvent resistant ion exchange resins to allow the use of alternative solvent based cleaning agents. Exemplary solvents include, but are not limited to, water, isopropyl alcohol (IPA), water/IPA mixtures, PETROFERM MEGASOLV JB, ZESTRON DS-100, and combinations thereof. PETROFERM MEGASOLV JB is a mixture thermodynamically stable blend of Propylene Glycol Methyl Ether Acetate (“PMA”) and Propylene Glycol Propyl Ether (“PNP”). Additional solvents and combinations may be used for various applications.

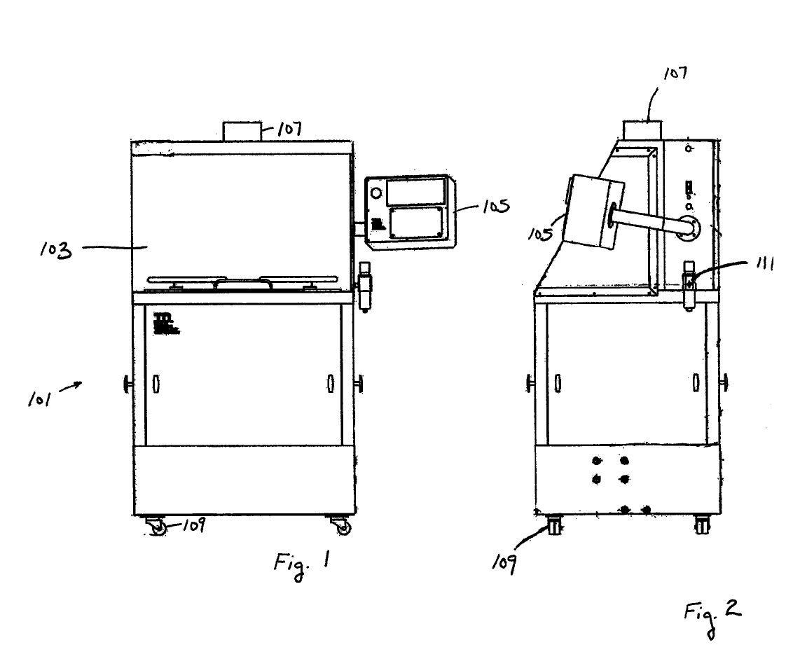

As shown in FIGS. 1 and 2, embodiments of the present invention may be portable, closed-loop, single-board cleaner 101 with cleanliness verification testing built-in. The system may have a small foot print, for example, 30″ by 36″. Other sizes may be used. The system may be manufactured with a stainless steel floor standing mobile cabinet. Other materials may be used, depending on the nature of the solvents used. The system may require an electrical connection, air and/or a nitrogen supply 111, and/or a vent. Optionally, the system may include lockable casters 109 to prevent unwanted movement.

Initially, an exemplary embodiment may be loaded with one or more electronic assemblies. One or more doors may open to empty a cleaning/testing chamber 103. One or more electronic assemblies may be placed directly into the chamber 103 or placed in a removable holder before placing into the cleaning/testing chamber. The one or more doors may be closed and locked. Preferably, the system cannot be started with the one or more doors open for safety reasons.

A user may select a process via a control panel 105, touch screen, switches, buttons, computer interface, etc. Options for may include clean only, test only, and/or clean and test. In certain embodiments, if a clean only process is selected, the user may be prompted to select process parameters; wash time, final rinse resistivity and dry time. If a test only process is selected, the user may be prompted to enter the surface area of the electronic assembly. Similar options may be available for clean and test processes. The cleaning fluid is soiled with ions in the wash cycle. This ionic soil is removed from the solvent in the rinse phase of the cleaning process. If a testing cycle specified, it can immediately follow the cleaning cycle. The rinse circulation of the wash fluid through the ion beds at the end of the wash cycle prepares the fluid for the ROSE test. Thus, the cleaning solvent is the testing solvent. A test sequence can be initiated immediately after completing the rinse sequence—no need to drain and refill the cleaning/test chamber. Alternative prompts and entries may be required for various applications. A user may then initiate the selected process.

Alternatively, in certain embodiments the selection of processes may be automatic. Automatic programs may be preprogrammed or customized for a particular application. The system may report results of the process to the user on a display, printout or other output mechanism.

The process tank may be a wash tank for cleaning. Features of the process tank may include a latch to secure a lid in position. The process tank may also include overflow port/tube to prevent process tank overfill. The overflow port/tube may drain directly into a wash fluid holding tank. Agitation nozzles may provide circulation of cleaning solution during a wash cycle. One or more of physical agitation and/or heating of the solvent may improve the dissolution rate. A physical agitator may include inputs/outputs, a circulation system, ultrasonic emitters, and others. Filling tubes may transfer cleaning solution from a holding tank to the process tank. One or more drain ports may accommodate drainage of the process tank into the holding tank. Alternatively, solvent may be filled into and removed from the process tank by pouring or other methods. Inputs and outputs are not required. Additionally, to improve sensitivity of the testing system, smaller volumes of solvent may be used. The process tank may be sized in various dimensions to reduce volume. Alternatively, embodiments of the present invention may include one or more removable dividers to reduce the effective volume of the process tank. In other embodiments, a fluid retaining bag may be filed with solvent and sealed. The fluid retaining bag may include one or more input or output ports. An air knife may dry cleaned parts. Once the fluids have been drained from the process tank, the fluids remaining on the parts and the fixtures can be dried by injecting heated or unheated air or inert gas such as nitrogen, into the sealed process chamber until the solvents evaporate. Drying can be accomplished with reduced pressure, but requires a vacuum tolerant chamber and lid with additional solenoids to isolate the tank. As indicated above, items to be cleaned may be placed in a basket and/or rack. The basket and/or rack may come in standard sizes or may be customized for particular applications. In some cases no holder would be required.

The exhaust port may exhaust fumes from the system. A properly ventilated system may emit little to no objectionable odor during operation.

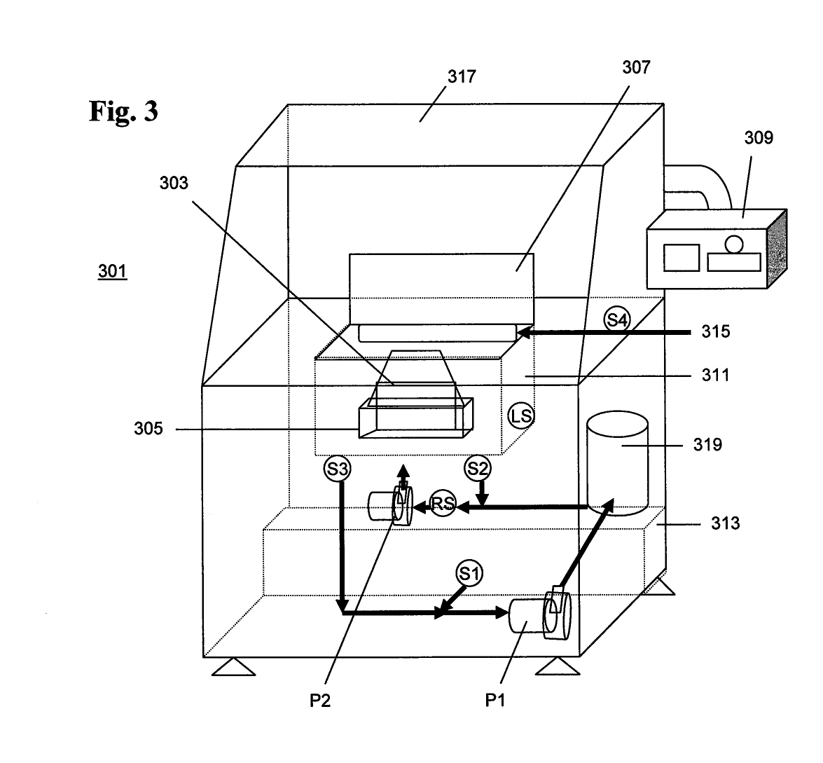

As shown in FIG. 3, embodiments of the present invention may include an apparatus for cleaning and/or testing 301. To operate the apparatus 301, an electronic assembly 303 may be loaded in a holder 305 that is then placed in a cleaning/testing chamber 311. The holder 305 may be optional and may be removable. A user may then close and/or secure a process tank door 307. An optional vent hood 317 may be included. A user may then select a process cycle and/or enter data at a controller 309. Ion exchange resin may be provided from an ion exchange resin tank 319. The selected process may then begin.

An automatic solvent fill sequence may commence. A normally closed solenoid S1 may be activated. A fill pump P1 may be activated to fill the cleaning/testing chamber to level determined by a level sensor LS with solvent from a solvent storage tank 313. Embodiments of the present invention may also include a device for physically agitating the solvent to improve the dissolution rate and an ion exchange resin to purify the test solvent. Once the predetermined level is met, fill pump P1 and solenoid S1 may be deactivated.

An optional flux cleaning sequence may be initiated if desired. Otherwise, the process may skip to the ROSE cleanliness test described below. To complete the flux cleaning sequence, the normally closed solenoid S2 may be activated. Wash pump P2 may be activated and run until a wash time requirement is met. Once the wash time requirement is met, wash pump P2 and solenoid S2 may be deactivated to end wash cycle. A rinse cycle may be initiated by activating solenoid S3 and fill pump P1. The rinse cycle may operate until a rinse resistivity requirement is met.

If no cleanliness test is required, then the cleaning/testing chamber 311 may be drained by activating solenoid S3 and solenoid S1. The apparatus 301 may proceed to a dry cycle.

If a cleanliness test is required, then the apparatus 301 runs a ROSE cleanliness test. Solenoid S2 and wash pump P2 may be activated. Resistivity may be recorded at the start of the cleanliness test and may continue recording until time, slope or other threshold requirements are met. The cleaning/testing chamber 311 may be drained by activating solenoid S3 and solenoid S1. At the close of the cleanliness test all solenoids may be closed and all pumps may be deactivated.

If a drying cycle is required, the dry cycle may be initiated by activating solenoid S4 to begin the flow of heated clean dry air, nitrogen or another gas 315. The dry cycle may operate until a dry time is met and/or a sensor indicates drying is complete.

Embodiments of the present invention may include a report function. A report may be displayed and/or printed for a user. A processor and memory may calculate a cleanliness value and/or report pass/fail data. The cleanliness and/or pass/fail data may be calculated based upon the measurements from a resistivity sensor and a comparison of those resistivity measurements to predetermined, threshold values.

Embodiments of the present invention may include the following features: power controls, operator interfaces, resistivity control module, process tank, and/or exhaust port 107. The operator interfaces may include self-prompting displays and controls to allow the user to initialize and/or change operating parameters. The resistivity control module may provide a signal to determine resistivity and may display the resistivity level of a cleaning solution based upon readings from a resistivity sensor. The sensing process may be based upon a relationship between resistivity of any polar solvent and the concentration of a given ionic species. The higher the concentration, the higher lower the resistance. It also can be said that the higher the concentration, the higher the conductance since electrical conductance is the reciprocal of electrical resistance. This is not a qualitative measurement to reveal the type of ion. It is semi-quantitative because different ions give different resistivity response based on ion mobility. The industry standard ROSE test is reported in NaCl equivalent ions per unit area of circuit assembly. This system reports the ionic concentration as if it were all NaCl, even though it is known that is not. The industry has set a limit for high reliability “class III” electronics to have less than 10 μg NaCl equivalent ions per in² or less than 1.56 μg NaCl equivalent ions per cm². Embodiments of the present invention may use this standard. The sensitivity of the test may be determined by volume of test solution used, the response curve for given solvent, and the accuracy and range of the resistance meter used to make the measurement. In certain embodiments, a resistance controller has a high limit of 90 megohms, which allow the use of most all oxygenated hydrocarbons and mixtures containing these. The testing/cleaning tank size may be sized as small possible to give maximum sensitivity.

Embodiments of the present invention may allow fully automated operation with minimal human oversight. The cleaning system may remove typical soldering fluxes (water soluble, RMA, no-clean, lead-free, etc.) in gaps sized one millimeter or less. The drying system may dry parts with high velocity air jets.

Embodiments of the present invention may use few consumables. Particulate filters and an immunoaffinity column/deionizing column are the only consumable parts requiring periodic replacement. An activated carbon filter could be added to pull high molecular weight non-polar soils from some cleaning solvents.

An exemplary embodiment may preferably have the following features: dry shipping weight of approximately 600 lbs; requires 110V (or 220V) depending on heater; vent of approximately 200-300 cfm; catch screens to prevent parts spilled from entering wash and rinse sumps; no exposed surfaces hotter than 100° F.; noise levels less than 70 decibels; UL compliant UL 1950 (standard); CE certifiable IEC-950/EN60950; CSA certifiable CSA C22.2 no. 950; meets NFPA 79; body constructed from stainless steel; seal and gaskets can be TEFLON, EDPM or BUNA-N; a wash tank selection of 1-10 gallons depending on assembly size and throughput; approximately 20 gallon holding tank; gravity drain to dump holding tank for maintenance; and cleaning process areas of up to 14″×12″×8″. These specifications are merely exemplary and may be varied depending on particular circumstances.

Embodiments of the present invention may allow for better detection of residual flux residues by allowing for use of solvent additives with solubility parameters better than alcohols and water mixtures. The new solvent blends can be formulated used with a wider range of fluxes by allowing the use of solvent constituents other than alcohol and water. The process can save process time and labor by allowing consolidation and automation of the cleaning process to remove flux residues, and the ROSE cleanliness test, used to verify final cleanliness, and the automatic drying of the assemblies, all in one operation. The new apparatus may be safer as it facilitates compliance with the National Electrical Code (NEC) and National Fire Protection Association (NFPA) codes.

Although the foregoing description is directed to the preferred embodiments of the invention, it is noted that other variations and modifications will be apparent to those skilled in the art, and may be made without departing from the spirit or scope of the invention. Moreover, features described in connection with one embodiment of the invention may be used in conjunction with other embodiments, even if not explicitly stated above.

What is claimed is:

1. An apparatus for cleaning and testing electronic assemblies, the apparatus comprising:
a cleaning/testing area for receiving one or more electronic assemblies;
one or more agitators for physically agitating one or more solvents within the cleaning/testing chamber;
a resistivity sensor for sensing resistivity of the one or more solvents removed from the cleaning/testing area through the solvent output; and
a processor and a memory for determining an amount of ionic residue on the one or more electronic assemblies by comparing the sensed resistivity of the one or more solvents removed from the cleaning/testing area and comparing the sensed resistivity to an original resistivity of the one or more solvents.

2. The apparatus of claim 1, wherein the one or more agitators are a circulation system.

3. The apparatus of claim 1, wherein the one or more solvents comprise a first component selected from the group consisting of a single alcohol, mixed alcohols, water, and combinations thereof, and a second component selected from the group consisting of one or more additional solvents, surfactants and combinations thereof.

4. The apparatus of claim 3, wherein the one or more additional solvents, surfactants and combinations thereof are selected based upon a resin used with the one or more electronic assemblies.

5. The apparatus of claim 1, further comprising a dryer.

6. The apparatus of claim 1, further comprising an ion exchange resin tank.

7. The apparatus of claim 1, further comprising one or more holders for the one or more electronic assemblies.

8. The apparatus of claim 1, further comprising a spray under immersion cleaning system for use within the cleaning/testing area.

9. The apparatus of claim 1, wherein the cleaning/testing area is constructed of materials compatible with the one or more solvents.

10. A method for cleaning and testing electronic assemblies, the method comprising:
loading one or more electronic assemblies into a cleaning/testing apparatus;
contacting the one or more electronic assemblies with one or more solvents;
measuring the resistivity of the one or more solvent after contact with the electronic assemblies;
comparing the resistivity of the one or more solvents after contact with the electronic assemblies with an original resistivity of the one or more solvents before contact with the electronic assemblies; and
determining the amount of ionic residues on the electronic assemblies based upon the comparing.

11. The method of claim 10, further comprising cleaning the one or more electronic assemblies prior to contacting the one or more electronic assemblies with a solvent.

12. The method of claim 11, wherein the cleaning is a spray under immersion cleaning process.

13. The method of claim 10, further comprising drying the electronic assemblies in the testing apparatus.

14. The method of claim 10, wherein the one or more solvents comprise a first component selected from the group consisting of a single alcohol, mixed alcohols, water, and combinations thereof, and a second component selected from the group consisting of one or more additional solvents, surfactants and combinations thereof.

15. The method of claim 14, wherein the one or more additional solvents, surfactants and combinations thereof are selected based upon a resin used with the one or more electronic assemblies.

16. A process for testing electronic assemblies, the process comprising:
providing a testing apparatus, wherein the testing apparatus comprises:
a cleaning/testing area for receiving one or more electronic assemblies;
a resistivity sensor;
a processor; and
a memory;
receiving one or more electronic assemblies into the cleaning/testing area;
initiating a cleaning cycle;
cleaning the one or more electronic assemblies;
initiating a testing cycle;
contacting the one or more electronic assemblies with one or more solvents;
measuring the resistivity, via the resistivity sensor, of the one or more solvents after contact with the one or more electronic assemblies;
comparing the resistivity of the one or more solvents after contact with the one or more electronic assemblies with an original resistivity of the one or more solvents before contact with the one or more electronic assemblies;
determining, via the processor and the memory, the amount of ionic residues on the one or more electronic assemblies based upon the comparing; and
drying the one or more electronic assemblies in the cleaning/testing area.

17. The apparatus of claim 16, wherein the one or more solvents comprise a first component selected from the group consisting of a single alcohol, mixed alcohols, water, and combinations thereof, and a second component selected from the group consisting of one or more additional solvents, surfactants and combinations thereof.

18. The apparatus of claim 17, wherein the one or more additional solvents, surfactants and combinations thereof are selected based upon a resin used with the one or more electronic assemblies.
